(19) United States
(12) Patent Application Publication
(10) Pub. No.: US 2002/0106857 A1
(43) Pub. Date: Aug. 8, 2002

(54) Method for surface area enhancement of capacitors by film growth and self masking

(75) Inventors: Rajarao Jammy, Wappingers Falls, NY (US); Irene McStay, Hopewell Jct, NY (US); Byeongju Park, Wappingers Falls, NY (US); Ravikumar Ramachandran, Ossining, NY (US); Joseph F. Shepard JR., Fishkill, NY (US); Helmut Tews, Poughkeepsie, NY (US)

Correspondence Address: FREDERICK W. GIBB, III, MCGINN & GIBB, PLLC, 2568-A RIVA ROAD, SUITE 304, ANNAPOLIS, MD, 21401, US

(73) Assignee: International Business Machines Corporation, Armonk, NY (US)

(21) Appl. No.: 09/777,445

(22) Filed: Feb. 6, 2001

(51) Int. Cl. H01L 21/8242; H01L 21/20

(52) U.S. Cl. 438/256

(57) ABSTRACT

A method and structure for a fabricating roughened surface walls of a capacitor, such as a deep trench capacitor. The invention starts with a silicon surface and forms silicon germanium grains on the silicon surface. A portion of the silicon surface remains exposed and is etched selective to the silicon germanium grains. The silicon germanium grains are then removed from the silicon surface. The silicon surface is doped after the silicon germanium grains are removed.

### BACKGROUND OF THE INVENTION

1. Field of the Invention

The present invention relates to semiconductor integrated circuits and, more particularly, to integrated circuits containing a deep trench memory cell.

2. Description of the Related Art

A memory cell in an integrated circuit comprises a transistor with an associated capacitor. The capacitor consists of a pair of conductive layers separated by a dielectric material. Information or data is stored in the memory cell in the form of charge accumulated on the capacitor. As the density of integrated circuits with memory cells is increased, the area for the capacitor becomes smaller and the amount of charge it is able to accumulate is reduced. Thus, with less charge to detect, reading the information or data from the memory cell becomes more difficult.

With a limited fixed space or volume for the capacitor of a memory cell in a highly integrated memory cell, there are three techniques for increasing the amount of charge within a fixed space or area; namely, 1) decrease the thickness of the dielectric material, 2) change the dielectric material to one with a higher dielectric constant, and 3) increase the surface area of the space to be used for the capacitor. Only technique 3) is a viable solution because technique 1), reducing the thickness of the dielectric, increases leakage currents which may effect the memory retention performance of the capacitor and the reliability of the memory cell. Technique 2), changing the dielectric material to one with a higher dielectric constant, will only cause a slight improvement in charge storage because the dielectric constant of suitable alternative dielectric materials is only slightly higher than the dielectric constant of the material presently being used. Moreover, the substitution of alternative dielectric materials may be more complicated, more expensive and provide unknown fabrication problems. Accordingly, technique 3), increasing the surface area of the space to be used for the capacitor, provides the most promise for substantially improving the amount of charge stored and without the disadvantages of increased leakage currents or fabrication problems of the other two techniques.

One previous solution to increase the surface area of the capacitor was to use a trench capacitor. An increase in the depth of the trench increased the surface area of the capacitor. However, the depth of the trench is limited by present fabrication methods and tools. This problem is compounded by the forever increasing density of integrated circuits which causes the width of the trench capacitor to be narrowed. To offset the loss of surface area by a reduction in the width, the depth of the trench must be further increased to the point where the necessary depth is not achievable or becomes prohibitively expensive.

To be able to continue to use a deep trench capacitor and to be able to increase the surface area, one prior art method and structure describes the use of capacitor plates with textured or roughened surfaces in the deep trench adjacent the dielectric material. A rough surface increases the amount of surface area due to the peaks and valleys of the rough surface of the plates. With this prior art method and structure, the depth of the trench is maximized and the rough surface of the plates is designed to give maximum surface area based on a cross-section of the rough surface so that the surface area is three dimensional at the interface of the plates and the dielectric material. However, the prior art method of creating a rough surface results in microscopic roughness, with sharp features or peaks of the order of a few Angstroms which may give rise to leakage through the dielectric material.

With increasing density of integrated circuits, especially integrated memory circuits, it is critical to have fabrication techniques which are easily adaptable to manufacturing for creating textured, patterned or roughened walls of the deep trench so as to increase the charge storage capability of the trench without current leakage. Accordingly, it is an object of the present invention to design a process for macroscopic roughening the walls of the capacitor, such as a trench capacitor which maximizes the three dimensional surface area of the capacitor at the maximum depth of the trench and eliminates current leakage. Further, it is object of the present invention to design a process for roughening the walls of the capacitor, such as a deep trench capacitor which does not result in sharp features in the rough walls of the completed deep trench.

### BRIEF DESCRIPTION OF THE DRAWINGS

The foregoing and other objects, aspects and advantages will be better understood from the following detailed description of preferred embodiments of the invention with reference to the drawings, in which:

FIG. 1 is a schematic diagram of a deep trench capacitor and accompanying pass transistor;

FIG. 2 is a schematic diagram of a stage of production of a deep trench capacitor;

FIG. 3 is a schematic diagram of a stage of production of a deep trench capacitor;

FIG. 4 is a schematic diagram of a stage of production of a deep trench capacitor;

FIG. 5 is a schematic diagram of germanium islands formed by the invention;

FIG. 6 is a schematic diagram of cross-sectional view of a germanium islands formed by the invention;

FIG. 7 is a schematic diagram of a silicon wall after the etching performed by the invention; and

FIG. 8 is a flow diagram illustrating a preferred method of the invention.

### SUMMARY OF THE INVENTION

To achieve these and other objects, a fabrication process of the present invention for roughening the surface walls of the capacitor, such as a deep trench capacitor, includes forming a high surface area silicon electrode. The method forms silicon germanium grains on the silicon surface. A portion of the silicon surface remains exposed. The invention etches the silicon surface selective to the silicon germanium grains and removes the silicon germanium grains from the silicon surface. The invention further includes doping the silicon surface after the removing of the silicon germanium grains.

The silicon germanium grains are formed by depositing silicon germanium on the silicon surface and nucleating the silicon germanium grains from the deposited silicon germanium on the surface. The silicon germanium grains form islands on the silicon surface and protect first regions of the silicon surface during the etching. The etching process creates irregularities by reducing a height of second regions of the silicon surface not protected by the germanium grains and the etching increases a surface area of the silicon surface.

### DETAILED DESCRIPTION OF PREFERRED EMBODIMENTS OF THE INVENTION

The invention comprises a method and system to increase the available surface area in the deep trench capacitors of advanced DRAM devices. Because electrical capacitance is proportional to the surface area of the dielectric, the charge available for data storage decreases with the advent of smaller structures. In order to keep the capacitance of the trench structure at or above design criteria, the invention utilizes the island growth common to the silicon/germanium system to produce a finely dispersed etch mask for additional surface roughening etch steps. The island masks are subsequently removed and the roughened trench coated with an appropriate dielectric to form the deep trench (DT) capacitor.

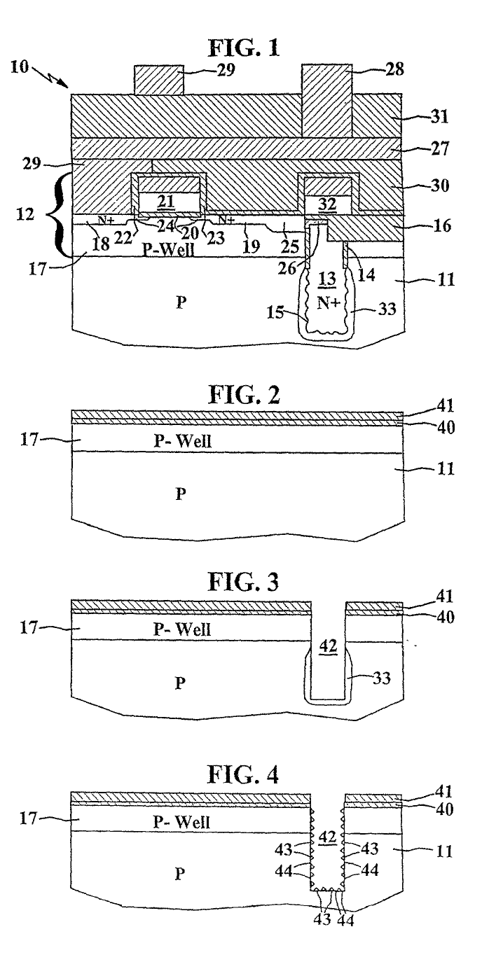

A detailed description of the present invention will now be made by referring to the accompanying drawings. FIG. 1 shows the basic parts of a memory cell 10, namely—a transistor and a capacitor, which is fabricated in and on a silicon substrate 11 and which, herein, is a small portion a dynamic random access memory (DRAM). The memory cell comprises a pair of field effect transistors (FET) of which only one FET 12 is indicated by a bracket. Associated with each FET is at least a pair of trench capacitors, which are connected to and in combination with each FET and of which only one capacitor 13 is shown. This memory cell is a component of a memory array of similar memory cells (not shown).

The capacitor 13 functions as a charge storage element and as a means for storing data in the memory cell 10. Disposed in the trench is N+ polysilicon. At the upper segment of the deep trench capacitor, an oxide collar 14 is disposed around the periphery 15 of the trench and abuts a shallow trench isolation (STI) area 16 on a side of the trench 13 opposite the FET 12. Herein, the FET 12 includes an N+ source region 18 and an N++drain region 19 in the silicon substrate 11 on opposite sides of a gate oxide 20 on and in the substrate 11 underlying a gate electrode 21 comprising doped polysilicon and a refractive metal. Insulating sidewalls 22 and 23 are disposed on the gate electrode 21 and were formed after the implantation of the—impurities adjacent the gate electrode, which created lightly doped drain (LDD) regions 24. The sidewalls 22 and 23 provide a mask for implanting the N+ impurities of the source and drain regions, 18 and 19, respectively. At the same time as the gate electrode 21 is formed, a conductive layer of doped polysilicon and refractive metal is disposed over and insulated from the trench by the STI 16 to provide a passover wordline 32.

Means for physically and electrically connecting the trench capacitor 13 to the FET comprises a deeper N+ region or strap 25 which is disposed in the drain region 19 as shown in FIG. 1. A conductive interposer 26 is positioned at the top of the trench 13 above the oxide collar 14 and abuts the N+ region or strap 25. To interface with other memory cells in the memory array, a bitline 27 extends above the gate electrode 21. Contact 28 is connected to the gate electrode 21 through a path not shown. Contact 29 is connected to the source 18 through a path not shown. Insulating layers 30 and 31 separate the contacts from the bitline and wordline contacts. The wordline, shown as the passover wordline 32, is part of the memory array and, through the interaction of the bitline 27 and the wordline, the capacitor of the present invention is charged and discharged in the writing and reading data into and out of the memory cell shown in FIG. 1. Another FET (not shown) and trench(es) (not shown) may be included in the memory cell adjacent to FET 12. In addition, additional trenches may be included adjacent the trench 13. Preferably, a doped conformal layer 33 doped with an impurity opposite to the substrate impurity is disposed in the lower segment of the trench. Herein, the layer 33 is glass doped with arsenic which diffuses into the substrate around the lower segment of the trench, as shown in FIG. 1, when heat treated at a suitable temperature. Alternatively, a dopant containing gas, such as arsine or phosphine may be employed.

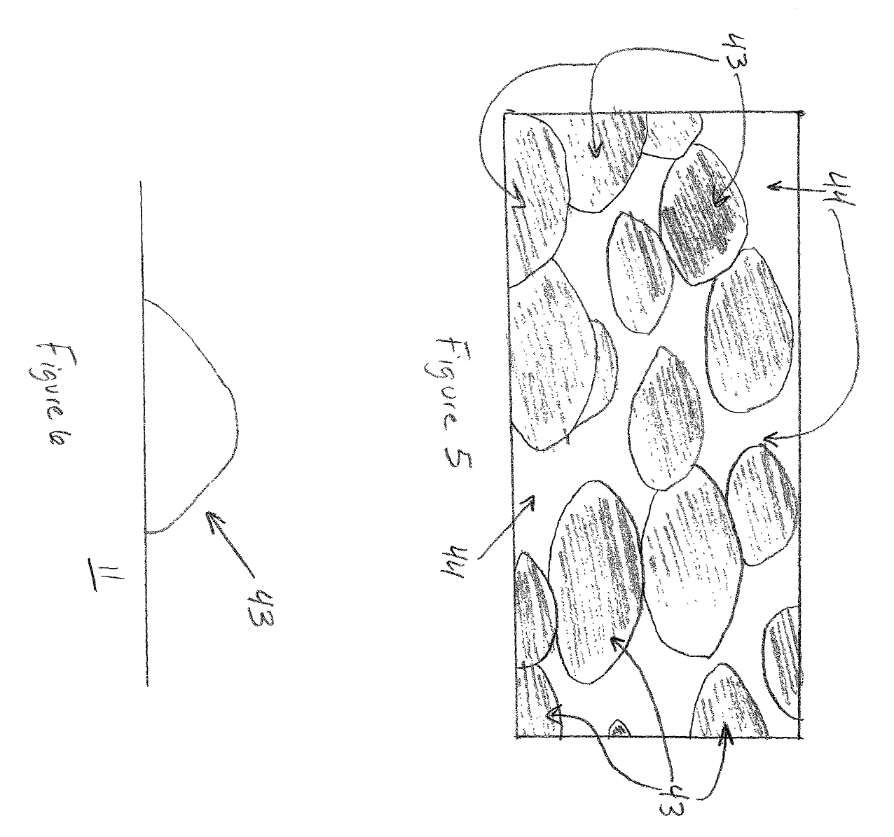

Referring now to FIG. 2-6 illustrated is a preferred embodiment of the trench capacitor of the present invention. Starting with FIG. 2, the P silicon substrate 11 of FIG. 1 is formed with the P-Well 17 by implanting P-impurities as part of the fabrication of the transistor. A pad oxide layer 40 is thermally grown in and on the substrate 11. Next, an insulating layer 41 with a different etch selectivity than the oxide layer 40, such as silicon nitride, is deposited on the oxide layer. Herein, the thickness of the silicon nitride is in the range of about 20 nm to about 500 nm and the preferred thickness is about 100 nm to about 300 nm.

Using reactive ion etching (RIE) and masking with a conventional photoresist, a trench opening 42 is formed in the silicon substrate 11 to a depth extending substantially beyond the metallurgical boundary of the P-Well as shown in FIG. 3. With the trench opening 42 formed, the side walls and bottom of the lower segment of the trench are doped with an N+ impurity 33 which, in the present instance, is from a conformal layer of glass containing arsenic which diffuses into the substrate 11 adjacent the trench opening as shown in FIG, 3. (Although this arsenic dopant remains present adjacent the trench side walls and bottom, it will not be shown again in the remaining drawings.) In an alternative embodiment, the dopant can be deposited after the shape of the surface of the deep trench is made irregular, as discussed below.

Next, islands of germanium 43 are formed on the silicon walls of the trench 42 (e.g., silicon germanium grains are nucleated from deposited silicon germanium on the surface of the trench 42. The islands of germanium provide a means to enhance node capacitance without increasing trench depth or replacing the node dielectric with a material of higher dielectric constant (i.e. high k). In a preferred embodiment, the invention utilizes the Stranski-Krastanov growth mode typical of the Ge/Si system (e.g., see F. M. Ross et al. Microsc. Microanal., 4, 254-263, 1998), incorporated herein by reference, to form the germanium islands. The processing used to form germanium islands is well known in the art field and will not be discussed in detail herein so as to not obscure the invention. In addition, as would be known by one ordinarily skilled in this art field, the Stranski-Krastanov growth mode can be used to form islands of other substances, such as cobalt, etc. Briefly, the substance (e.g., germanium, cobalt, etc.) is deposited on the silicon surface to form silicon germanium deposits. Then silicon germanium grains are nucleated from the deposited silicon germanium, whereby a portion of the silicon surface remains exposed and is subsequently etched.

The germanium islands 43 provide an appropriate etch mask for surface area enhancement of the trench capacitor structure. The islands are deposited, the trench walls etched, the islands removed, and the dielectric deposited. Because of the relative ease with which germanium alloys with silicon, surface grains can be deposited with an extensive range of compositions leading to further control of surface morphology, etch properties, and deposition conditions.

Etching the trench walls can be accomplished with a number of etchants both wet and dry. Previous work on the wet etching of silicon selective to germanium has investigated solutions of KOH:K₂Cr₂0₇:H₂0:propanol and ethylenediamine: pyrocatechol: water (as reviewed by Carns et al., J. Electrochemical Soc., 142, 4, 1260), incorporated herein by reference. Work on the dry etching of the silicon germanium system has been conducted with SF6/H2/CF4 plasmas (Bestwick et al., IBM Technical Disclosure Bulletin, 1992), incorporated herein by reference. In both cases selectivities have been reported at better than a 10:1 ratio.

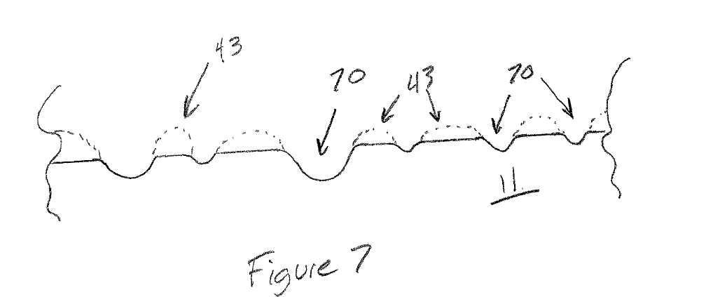

An enlarged schematic drawing of the germanium islands 43 and the exposed silicon 44 is illustrated in FIG. 5. FIG. 6 is a schematic cross-sectional diagram of one of the germanium islands 43. FIG. 7 is a cross-sectional diagram of the silicon wall of the deep trench capacitor 11 after etching and after removal of the germanium islands 43. For reference, the areas where the germanium islands 43 existed are shown with dashed lines. The etching produces depressions 70 in the surface of the silicon wall 11. These depressions 70 (which are not drawn to scale) increase the surface area of the silicon and, as explained above, thereby increase the capacitance of the deep trench capacitor. The depth of the depressions 70 is controlled by the etching process. Therefore, the depressions 70 can be made deeper or shallower depending upon the requirements of the designer.

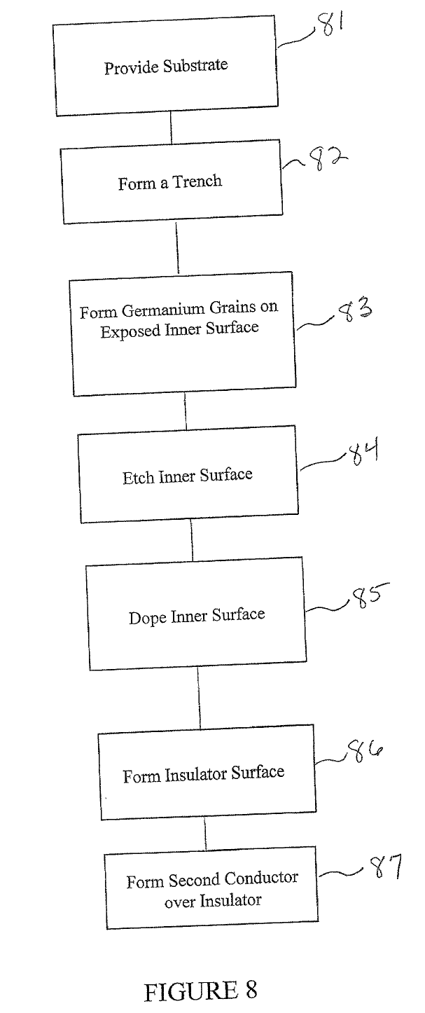

FIG. 8 is a flowchart detailing the steps involved in achieving the process for the invention. The process begins with providing a substrate 81. Next, a trench is formed in the substrate 82. Then germanium grains are formed on said inner surface 83 and the inner surface is etched 84. The inner surface is doped 85 and an insulator surface is formed 86. The invention then proceeds to form a second conductor over the insulator 87.

With the fabrication of the trench opening of the preferred embodiment of the present invention completed, the remaining process steps are conventional and well know in the art and will not be described in great detail. Briefly, the region of the substrate 11 can be doped with an impurity 33 to form a conductor, an insulator can formed over the uneven surface of the silicon wall 11 and then the deep trench 42 can be filled at least partially with a conductor to form the capacitor discussed above.

Previous methods have used Ge nucleation for surface area enhancement (e.g., see U.S. Pat. No. 5,384,152, incorporated herein by reference); However, such previous work does not use the assembled islands as an etch mask. Rather, such conventional teachings improved the capacitor's surface area by the utilization of the surface as-deposited. In other words conventionally, germanium nuclei were deposited and the capacitor was formed on top of the germanium islands (SiGe/poly-Si/SiO2/poly-Si). To the contrary, in the present invention, the deposited material is utilized as a mask during a subsequent wet/dry etch of the trench walls and then removed.

Another conventional structure used to increase surface area used “bottle trenches” to enhance the node capacitance of DRAM cells (e.g., see Rupp et al., IEDM, 1999, incorporated herein by reference). In such conventional processes, steps are taken to etch the trench, mask an upper region, and then continue to etch the exposed area in the lower half of the trench. The extended perimeter of the “bottle” trench provides additional surface area for the subsequent deposition of the node dielectric and thus increases trench capacitance.

Another conventional technique, involves the formation of rough poly-Si or Hemispherical Silicon Grains (HSG). HSG formation requires the deposition of an a-Si film, seeding of this layer and a subsequent high vacuum nucleation step. The grain structure of HSG-nucleated Si is often re-entrant (mushroom-like). During subsequent processing, the re-entrant structure often results in the undercutting and breakage of individual grains. This potentially limits the scalability of HSG technique to finer dimensions of DRAMs, especially for stack capacitors that employ cylindrical and complex fin structures for charge storage. Currently, many DRAM manufactures are battling poor reliability stemming from bridging/collapse of Si grains and from spatial constraints between neighboring stacks.

In contrast to the HSG technique, the present invention yields a coherent interface (see FIG. 5) and thus overcomes the difficulties inherent to that process (e.g. re-entrant grain structure). Furthermore, Stranski-Krastanov nucleation and masking techniques can be used in conjunction with “bottle trenches” and the low temperatures employed make the process amenable to stack capacitor fabrication.

While the invention has been described in terms of preferred embodiments, those skilled in the art will recognize that the invention can be practiced with modification within the spirit and scope of the appended claims.

1. A method of forming a high surface area silicon electrode, said method comprising:
providing a silicon surface;
forming grains on said silicon surface, whereby a portion of said silicon surface remains exposed;
etching said silicon surface selective to said grains; and
removing said grains from said silicon surface.

2. The method of claim 1, further comprising doping said silicon surface after said removing of said grains.

3. The method in claim 1, wherein said forming of said grains comprises:
depositing silicon germanium on said silicon surface; and
nucleating silicon germanium grains from said deposited silicon germanium on said surface.

4. The method in claim 1, wherein said grains comprise islands on said silicon surface and protect first regions of said silicon surface during said etching.

5. The method in claim 4, wherein said etching process creates irregularities by reducing a height of second regions of said silicon surface not protected by said grains.

6. The method in claim 1, wherein said etching increases a surface area of said silicon surface.

7. A method of forming a high surface area capacitor structure, said method comprising:
providing a surface;
forming germanium grains on said surface, whereby a portion of said surface remains exposed;
etching said surface selective to said germanium grains;
removing said germanium grains from said surface;
doping said surface to make said surface a first conductor;
forming an insulator over said surface; and
forming a second conductor over said insulator.

8. The method of claim 7, further comprising doping said surface after said removing of said silicon germanium grains.

9. The method in claim 7, wherein said forming of said germanium grains comprises:
depositing germanium on said surface; and
nucleating said germanium grains from said deposited germanium on said surface.

10. The method in claim 7, wherein said germanium grains comprise islands on said surface and protect first regions of said surface during said etching.

11. The method in claim 10, wherein said etching process creates irregularities by reducing a height of second regions of said surface not protected by said germanium grains.

12. The method in claim 7, wherein said etching increases a surface area of said surface.

13. The method in claim 7, wherein said surface comprises a silicon surface and said germanium grains comprise silicon germanium.

14. A method of forming a high surface area trench capacitor structure, said method comprising:
providing a substrate;
forming a trench in said substrate, said trench having an inner surface;
forming germanium grains on said inner surface, whereby a portion of said inner surface remains exposed;
etching said inner surface selective to said germanium grains;
removing said germanium grains from said inner surface;
doping said inner surface to make said inner surface a first conductor;
forming an insulator over said inner surface; and
forming a second conductor over said insulator.

15. The method of claim 14, further comprising doping said inner surface after said removing of said germanium grains.

16. The method in claim 14, wherein said forming of said germanium grains comprises:
depositing germanium on said inner surface; and
nucleating said germanium grains from said deposited germanium on said inner surface.

17. The method in claim 14, wherein said germanium grains comprise islands on said inner surface and protect first regions of said inner surface during said etching.

18. The method in claim 17, wherein said etching process creates irregularities by reducing a height of second regions of said inner surface not protected by said germanium grains.

19. The method in claim 14, wherein said etching increases an inner surface area of said inner surface.

20. The method in claim 14, wherein said inner surface comprises a silicon inner surface and said germanium grains comprise silicon germanium.
